(19) United States
(12) Patent Application Publication
(10) Pub. No.: US 2024/0170296 A1
(43) Pub. Date: May 23, 2024

(54) METHOD FOR FORMING SEMICONDUCTOR STRUCTURE AND SEMICONDUCTOR STRUCTURE

(71) Applicant: WINBOND ELECTRONICS CORP., Taichung City (TW)

(72) Inventors: Hung-Jung YAN, Tainan City (TW); Chun-Chieh WANG, Taichung City (TW); Tzu-Ming OU YANG, Taichung City (TW)

(21) Appl. No.: 18/493,240

(22) Filed: Oct. 24, 2023

(30) Foreign Application Priority Data
Nov. 18, 2022 (TW) 111144175

(51) Int. Cl. H01L 21/308; H01L 21/033; H01L 21/311

(52) U.S. Cl. CPC H01L 21/3086; H01L 21/0337; H01L 21/31144

(57) ABSTRACT

A method for forming a semiconductor structure includes forming strip patterns over a semiconductor substrate, forming a hard mask layer over the strip patterns, and forming a patterned photoresist layer over the hard mask layer. The patterned photoresist layer has a plurality of first openings. The method also includes etching the hard mask layer using the patterned photoresist layer. Remaining portions of the hard mask layer form a plurality of pillar patterns that are separated from one another. The method also includes depositing a dielectric layer along the plurality of pillar patterns, etching the dielectric layer to form a plurality of second openings, removing the plurality of pillar patterns to form a plurality of third openings in the dielectric layer, and etching the strip patterns using the dielectric layer as a mask.

### CROSS REFERENCE TO RELATED APPLICATIONS

This application claims the benefit of Taiwan Patent Application No. 111144175 filed on Nov. 18, 2022, entitled “METHOD FOR FORMING SEMICONDUCTOR STRUCTURE AND SEMICONDUCTOR STRUCTURE” which is hereby incorporated herein by reference.

### BACKGROUND

### Field of the Disclosure

The present disclosure relates to a method for forming a semiconductor structure, and in particular, it relates to a method for forming active regions of a semiconductor structure.

### Description of the Related Art

In order to increase DRAM density and improve its performance, existing technologies for fabricating DRAM devices continue to focus on scaling down the DRAM's size.

### SUMMARY

The method of forming a semiconductor structure includes forming strip patterns over a semiconductor substrate, forming a hard mask layer over the strip patterns, and forming a patterned photoresist layer over the hard mask layer. The patterned photoresist layer has a plurality of first openings. The method also includes etching the hard mask layer using the patterned photoresist layer. Remaining portions of the hard mask layer form a plurality of pillar patterns that are separated from one another. The method also includes depositing a dielectric layer along the plurality of pillar patterns, etching the dielectric layer to form a plurality of second openings, removing the plurality of pillar patterns to form a plurality of third openings in the dielectric layer, and etching the strip patterns using the dielectric layer as a mask.

The method of forming a semiconductor structure includes forming a plurality of strip patterns over a semiconductor substrate, forming a first hard mask layer over the plurality of strip patterns, and patterning the first hard mask layer to form a plurality of pillar patterns corresponding to the plurality of strip patterns. The plurality of pillar patterns have diamond-like profiles. The method also includes forming a spacer layer surrounding the plurality of pillar patterns. The spacer layer has a plurality of first openings staggered from the plurality of pillar patterns, and the plurality of first openings have diamond-like profiles. The method also includes removing the pillar patterns to form a plurality of second openings, and etching the strip patterns using the spacer layer as a mask.

The semiconductor structure includes a substrate, strip patterns over the substrate, and a spacer layer over the strip patterns. The spacer layer has a plurality of openings corresponding to the strip patterns and arranged in an array. The plurality of openings includes first openings arranged in a first row of the array, and second openings arranged in a second row of the array. The first openings are staggered from the second openings, and both the first openings and the second openings have diamond-like profiles.

### BRIEF DESCRIPTION OF THE DRAWINGS

In accordance with some embodiments of the present disclosure, it can be further understood by reading the subsequent detailed description and examples with references made to the accompanying drawings, wherein:

FIGS. 1A to 8A illustrate plan views of forming a semiconductor structure at various stages, in accordance with some embodiments of the present disclosure.

FIGS. 1B to 8B illustrate cross-sectional views of the semiconductor structure tacked along line A-A and line B-B of FIGS. 1A to 8A, in accordance with some embodiments of the present disclosure.

FIGS. 9A and 9B illustrate some details of pillar patterns.

FIGS. 10A and 10B illustrate some details of gaps patterns.

### DETAILED DESCRIPTION

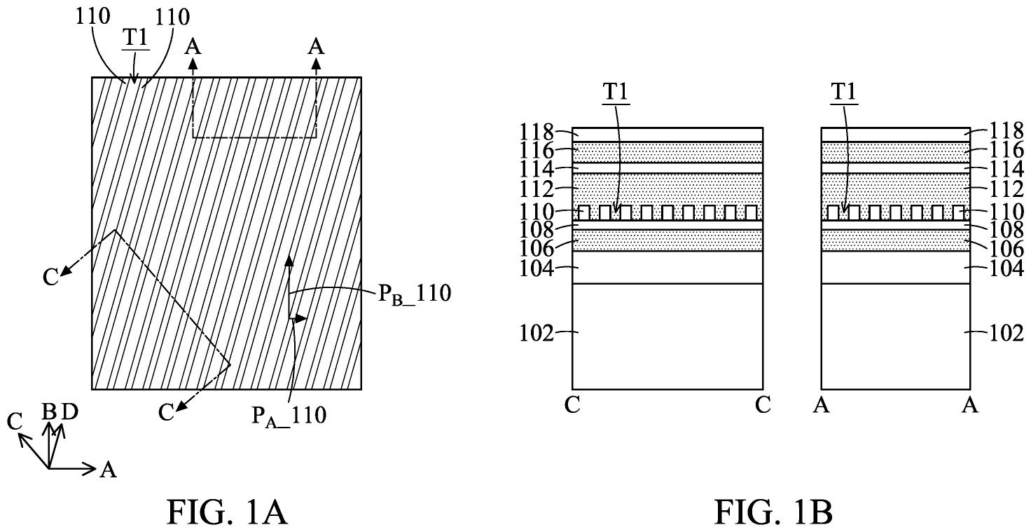

FIGS. 1A to 8A illustrate plan views of forming a semiconductor structure at various stages, in accordance with some embodiments. The plan views only show some components of the semiconductor structure for brevity and clarity. Some other components of the semiconductor structure may be shown in the cross-sectional views of FIGS. 1B to 8B.

For ease of illustration, FIGS. 1A to 8A illustrate reference directions, in that directions A, B, C and D are horizontal directions. The first direction A is parallel to the row direction of an array formed by core patterns. The second direction B is parallel to the column direction of the array formed by the core patterns. The first direction A is substantially perpendicular to the second direction B. The third direction C is parallel to the diagonal direction of the array formed by the core patterns. The third direction C intersects with the second direction B at an acute angle. The fourth direction D is parallel to the extension direction of active regions. The fourth direction D intersects with the second direction B at an acute angle, which is smaller than the acute angle between the third direction C and the second direction B.

FIGS. 1A to 8A further illustrate reference cross-sections, in that cross-section A-A′ is a plane that is parallel to the first direction A and passes through a row of the core patterns, and cross-section C-C is a plane that is parallel to the third direction C and passes through the core patterns disposed on the diagonal of the array. FIGS. 1B to 8B illustrate cross-sectional views of the semiconductor structure taken along cross-section A-A and cross-section C-C of FIGS. 1A to 8A.

A semiconductor substrate 102 is provided, as shown in FIG. 1B. In some embodiments, the semiconductor substrate 102 is an elemental semiconductor substrate, such as a silicon substrate, or a germanium substrate; or a compound semiconductor substrate, such as a silicon carbide substrate, or a gallium arsenide substrate.

A first patterned mask layer 104, a second hard mask layer 106, a third hard mask layer 108, a patterned mask layer 110, a fourth hard mask layer 112, a fifth hard mask layer 114, a sixth hard mask layer 116, and a seventh hard mask layer 118 are sequentially formed over the semiconductor substrate 102, as shown in FIGS. 1A and 1B.

In some embodiments, the first patterned mask layer 104, the third hard mask layer 108, the fifth hard mask layer 114 and the seventh hard mask layer 118 are made of silicon-containing dielectric material, for example, silicon oxide, silicon oxynitride (SiON), silicon-rich silicon oxynitride (Si—SiON), oxygen-rich silicon oxynitride (O—SiON), and/or silicon nitride (SiN). The first patterned mask layer 104, the third hard mask layer 108, the fifth hard mask layer 114 and the seventh hard mask layer 118 may be made of different materials.

In some embodiments, the second hard mask layer 106, the fourth hard mask layer 112 and the sixth hard mask layer 116 are made of a carbon-rich material, such as carbon, amorphous carbon, diamond-like carbon (DLC), high selectivity transparency (HST) film, and/or spin-on carbon (SOC). The second hard mask layer 106, the fourth hard mask layer 112 and the sixth hard mask layer 116 may be made of different materials.

In some embodiments, the patterned mask layer 110 is made of semiconductor material such as polysilicon. The patterned mask layer 110 includes multiple strip patterns spaced apart from each other at approximately equal distances, as shown in FIG. 1A. The strip patterns of the patterned mask layer 110 are separated by trenches T1, which expose the third hard mask layer 108. The strip patterns of the patterned mask layer 110 and the trenches T1 extend in the fourth direction D. The patterned mask layer 110 may be formed by depositing semiconductor material followed by a patterning process (including lithography and etching processes). The fourth hard mask layer 112 is formed over the patterned mask layer 110 and fills the trenches T1 between the strip patterns.

The strip patterns of the patterned mask layer 110 have a pitch PA_110 in the first direction A and a pitch PB_110 in the second direction B. In some embodiments, the pitch PB_110 is greater than the pitch PA_110. As used herein, the pitch refers to the sum of the size of one pattern itself and the distances between adjacent patterns in a particular direction.

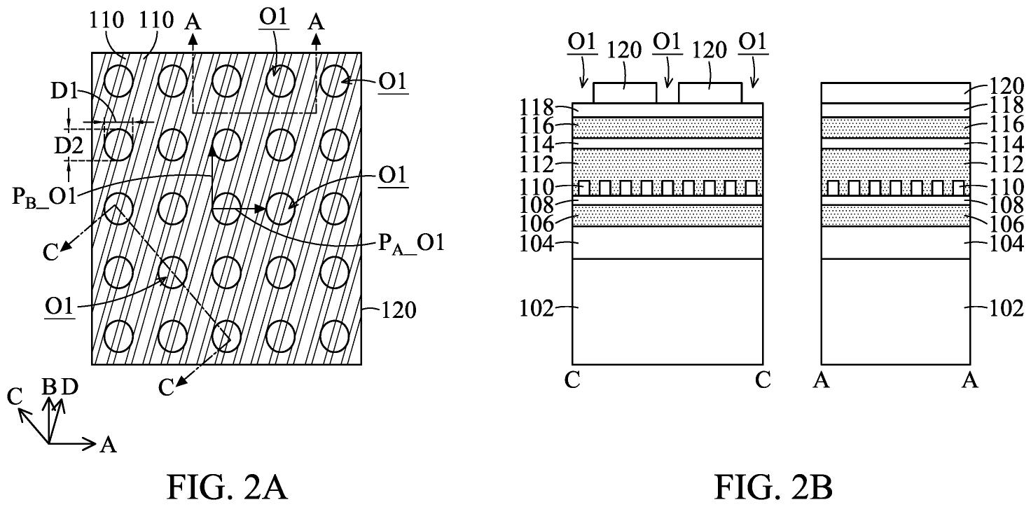

The patterned photoresist layer 120 is formed over the seventh hard mask layer 118, as shown in FIGS. 2A and 2B. The patterned photoresist layer 120 has multiple openings O1 that are separated from one other and expose the seventh hard mask layer 118. The patterned photoresist layer 120 may be form by coating a photoresist using a spin-coating process, followed by a lithography process.

The openings O1 of the patterned photoresist layer 120 are arranged in an array in the first direction A (i.e., row direction) and the second direction B (i.e., column direction). The openings O1 overlap (or are aligned with) the strip patterns of the patterned mask layer 110. The openings O1 have a pitch P_{A}_O1 in the first direction A and a pitch P_{B}_O1 in the second direction B. The pitch P_{B}_O1 may be larger than the pitch P_{A}_O1. The pitch P_{B}_O1 is substantially equal to the pitch P_{B}_110 of the strip patterns. The pitch P_{A}_O1 is larger than the pitch P_{A}_110 of the strip patterns, for example, the pitch P_{A}_O1 is approximately twice the pitch P_{A}_110. The ratio of pitch P_{A}_O1 to pitch P_{B}_O1 may be in a range from about 0.75 to about 0.95.

The openings O1 have elliptical profiles, as shown in FIG. 2A. The opening O1 has a dimension D1 in the first direction A and a dimension D2 in the second direction B. The ratio of dimension D1 to dimension D2 may be in range from about 0.65 to about 0.9. In some other embodiments, the openings O1 may have circular profiles.

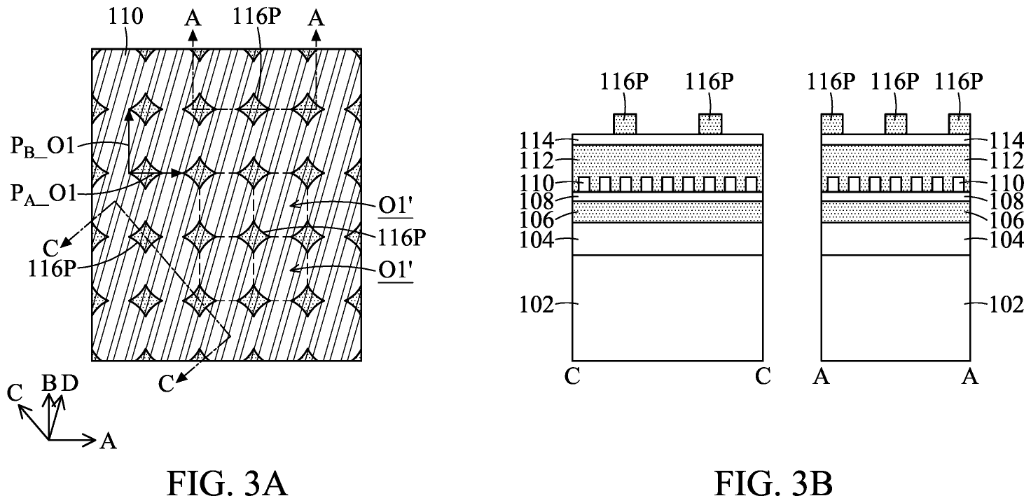

An etching process is performed on the semiconductor structure of FIGS. 2A and 2B using the patterned photoresist layer 120 to remove the seventh hard mask layer 118 and the sixth hard mask layer 116 directly under the openings O1, until the fifth hard mask layer 114 is exposed, as shown in FIGS. 3A and 3B. The patterned photoresist layer 120 and the seventh hard mask layer 118 may be removed during the etching process, or by additional processes.

The etching process includes etching steps and trimming steps. The etching step vertically transfers the openings O1 of the patterned photoresist layer 120 into the sixth hard mask layer 116, while the trimming step horizontally etches the sixth hard mask layer 116 to enlarge the openings O1 in the sixth hard mask layer 116. The enlarged openings O1 are denoted as O1′, as shown in FIGS. 3A and 3B. The trimming step is performed until two neighboring openings O1′ in the same row and/or same column are connected (or bridged) to each other.

The connected openings O1′ divide the sixth hard mask layer 116 into multiple separated pillar patterns 116P. Each pillar patterns 116P is located between four openings O1′ at the intersections of adjacent two columns and adjacent two rows, as shown in FIG. 3A. The pillar patterns 116P are also referred to as core patterns.

The pillar patterns 116P are arranged in an array in the first direction A (row direction) and the second direction B (column direction). The pillar patterns 116P overlap (or are aligned with) the strip patterns of the patterned mask layer 110. The pillar patterns 116P have the same pitch P_{A}_O1 and pitch P_{B}_O1 as the openings O1.

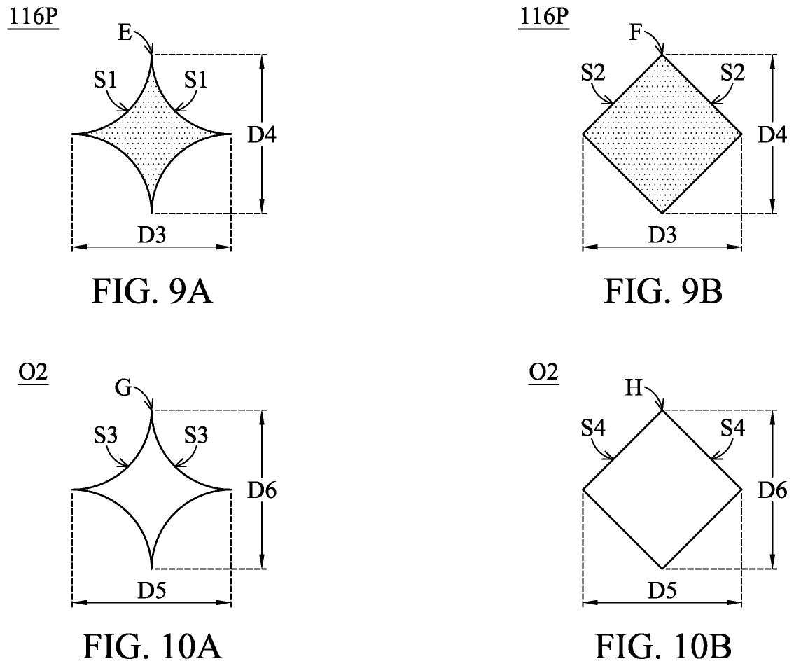

FIGS. 9A and 9B illustrate some details of the pillar patterns 116P. As shown in FIG. 9A, the pillar patterns 116P may have diamond-like profiles. The profile of the pillar pattern 116P may have four concave sides (or sidewalls) S1. Two sides S1 intersect at a sharp angle E. In some embodiments, the pillar patterns 116P may have diamond-shaped profiles, as shown in FIG. 9B. The profile of the pillar pattern 116P has four linear sides S2. The angle F at which two sides S2 intersect may be in a range from about 60 degrees to about 120 degrees. The pillar pattern 116P has a dimension D3 in the first direction A and a dimension D4 in the second direction B. The ratio of dimension D3 to dimension D4 may be in a range from about 0.6 to about 1.7. Although FIGS. 9A and 9B illustrate the profiles of the pillar patterns 116P, they are not limited thereto. For example, by adjusting the parameters of the etching process, the diamond-like profiles of the pillar patterns 116P may also have four convex sides.

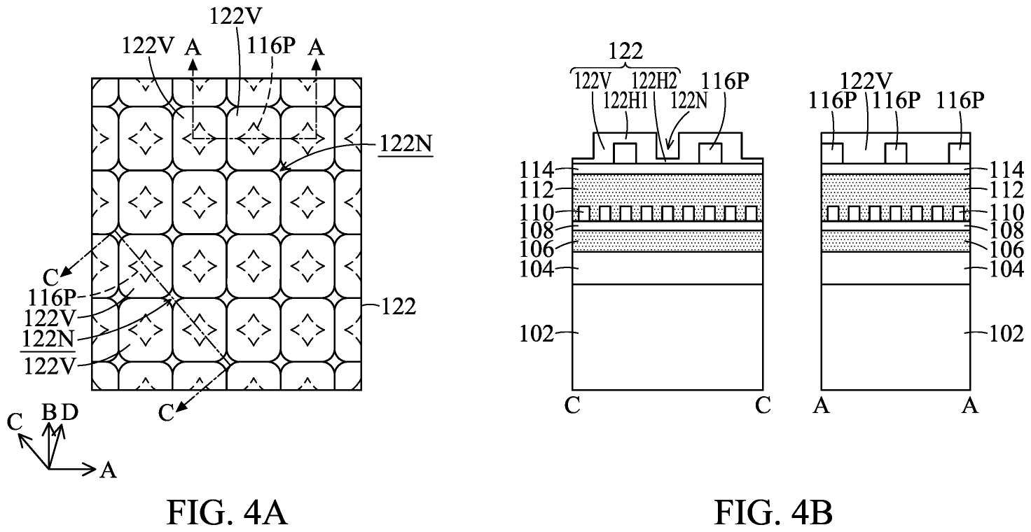

Afterward, a dielectric layer 122 is formed along the sidewalls and the top surfaces of the pillar patterns 116P, as well as along the top surface of the fifth hard mask layer 114, as shown in FIGS. 4A and 4B. In some embodiments, the dielectric layer 122 is made of dielectric material such as silicon oxide (SiO), silicon nitride (SiN), or silicon oxynitride (SiON). The dielectric layer 122 may be deposited using atomic layer deposition (ALD), chemical vapor deposition (CVD), or other suitable techniques.

The dielectric layer 122 includes first horizontal portions 122H1 along the top surfaces of the pillar patterns 116P, second horizontal portions 122H2 along the top surface of the fifth hard mask layer 114, and vertical portions 122V along the sidewalls of the pillar patterns 116P. The deposition process is performed until two neighboring vertical portions 122V merge (or bridge) with each other. Specifically, the merging of vertical portions 122V occurs in the first direction A and the second direction B, but in the third direction C the vertical portions 122V do not merge. For illustrative purposes, FIG. 4A shows the interface between the vertical portions 122V. However, there may be no substantial interface between the vertical portions 122V.

Upon completion of the deposition process, the spaces between these pillar patterns 116P are divided into multiple gaps 122N which are separated from each other. Each gap 122N is located between four pillar patterns 116P at the intersections of two neighboring columns and two neighboring rows, and above a second horizontal portion 122H2. The gaps 122N are arranged in an array in the first direction A (row direction) and the second direction B (column direction). The gaps 122N may have a diamond-shaped or diamond-like profile.

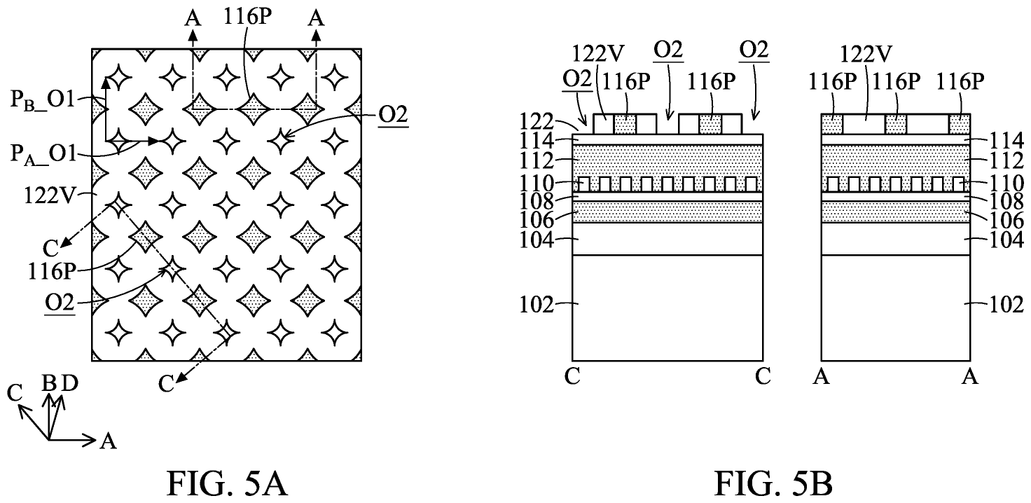

An etching process is performed on the dielectric layer 122 to remove the first horizontal portions 122H1 and the second horizontal portions 122H2 of the dielectric layer 122, until the pillar patterns 116P and the fifth hard mask layer 114 are exposed, as shown in FIGS. 5A and 5B. After the etching process, the vertical portions 122V of the dielectric layer 122 remain as a spacer layer. The etching process vertically enlarges the gaps 122N, thereby forming openings O2 which expose the fifth hard mask layer 114. The openings O2 are also referred to as gap patterns.

The openings O2 are arranged in an array in the first direction A (row direction) and the second direction B (column direction). The openings O2 overlap (or are aligned with) the strip patterns of the patterned mask layer 110. The openings O2 have the same pitch P_{A}_O1 and pitch P_{B}_O1 as the openings O1.

FIGS. 10A and 10B illustrate some details of the openings O2. As shown in FIG. 10A, the openings O2 may have diamond-like profiles. The profile of the opening O2 has four concave sides S3. Two sides S3 intersect at a sharp angle G. In some embodiments, the openings O2 may have diamond-shaped profiles, as shown in FIG. 10B. The profile of the opening O2 has four linear sides S4. The angle H at which two sides S4 intersect may be in a range from about 60 degrees to about 120 degrees. The opening O2 has a dimension D5 in the first direction A and a dimensions D6 in the second direction B. The ratio of dimension D5 to dimension D6 may be in a range from about 0.6 to about 1.7. Although FIGS. 10A and 10B illustrate the profiles of the openings O2, they are not limited to thereto. For example, by adjusting the parameters of the etching process, the diamond-like profiles of the openings O2 may have four convex sides.

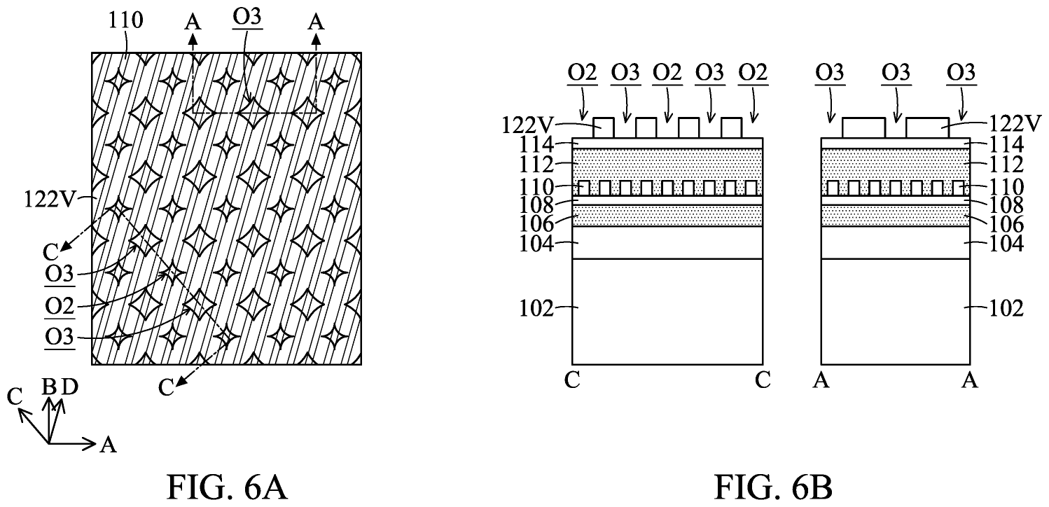

Afterward, an etching process is performed to remove the pillar patterns 116P, thereby forming openings O3, as shown in FIGS. 6A and 6B. The openings O3 expose the fifth hard mask layer 114. The openings O3 are arranged in an array in the first direction A (row direction) and the second direction B (column direction). The openings O3 alternate and are staggered from the openings O2 in the second direction B. The profiles, dimensions, and arrangement of the openings O3 are substantially similar to the profiles, dimensions, and arrangement of the pillar patterns 116P, and thus will not be further described. Although FIG. 6A shows that the dimensions of the openings O2 are smaller than the dimensions of the openings O3, in some embodiments, the dimensions of the openings O2 may be equal to or larger than the dimensions of the openings O3. After the removal of the pillar patterns 116P, the spacer layer 122V has core patterns (i.e., openings O3) and gap patterns (i.e., openings O2). The spacer layer 122V is configured as an etch mask for subsequent formation of the active regions.

According to embodiments of the present disclosure, the core patterns and the gap patterns have approximate profiles, such as both having diamond-like or diamond-shaped profiles. As a result, there is better pattern balance between the core patterns and the gap patterns, which may help improve the detection capability of measuring devices during after-etch inspection (AEI). Therefore, wafers with patterns that do not comply with control specifications can be detected early in the semiconductor manufacturing process, thereby reducing the manufacturing cost of semiconductor memory devices and improving the manufacturing yield of the semiconductor memory devices. In addition, the pillar patterns 116P are made of a hard mask material (e.g., carbon) with better rigidity than photoresist material. Therefore, the risk of core pattern delamination or distortion may be reduced.

Furthermore, the dimensions of the core patterns are defined by the pillar patterns 116P, while the dimensions of the gap patterns depend on the thickness of the spacer layer 122V. Compared to situations where both the core patterns and the gap patterns are simultaneously generated by forming the spacer layer, the method of the present disclosure allows for independent adjustment of the dimensions of the gap patterns (by adjusting the thickness of the spacer layer 122V) without affecting the dimensions of the core patterns. Therefore, the process difficulty of manufacturing the semiconductor memory device may be reduced.

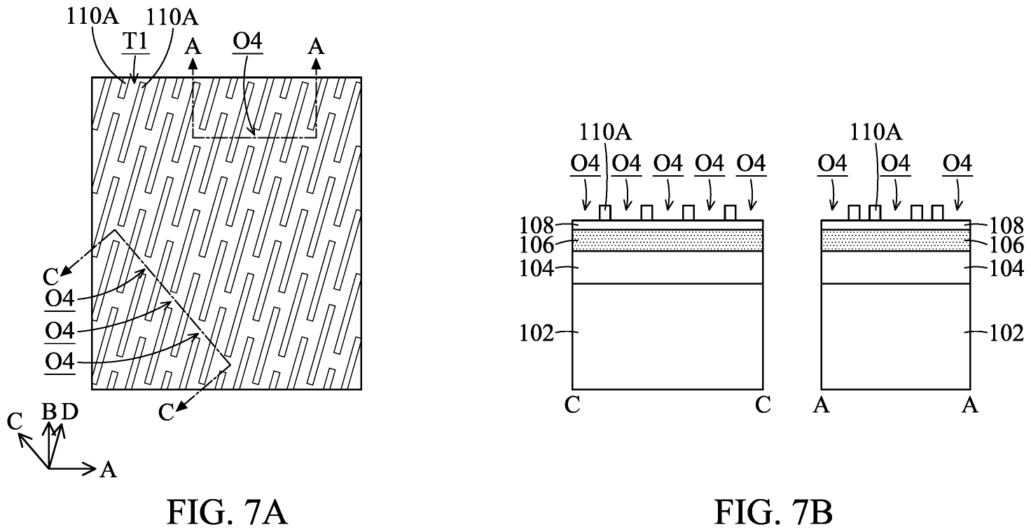

One or more etching processes are performed on the semiconductor structure of FIGS. 6A and 6B using the spacer layer 122V to remove the fifth hard mask layer 114, the fourth hard mask layer 112, and the patterned mask layer 110 directly under the openings O2 and O3, until the third hard mask layer 108 is exposed, as shown in FIGS. 7A and 7B. The spacer layer 122V, the fifth hard mask layer 114, and the fourth hard mask layer 112 may be removed during the etching process or by additional processes. The etching process transfers the openings O2 and O3 of the spacer layer 122V into the patterned mask layer 110, thereby forming openings O4. The openings O4 cut off the strip patterns of the patterned mask layer 110 into multiple island patterns 110A.

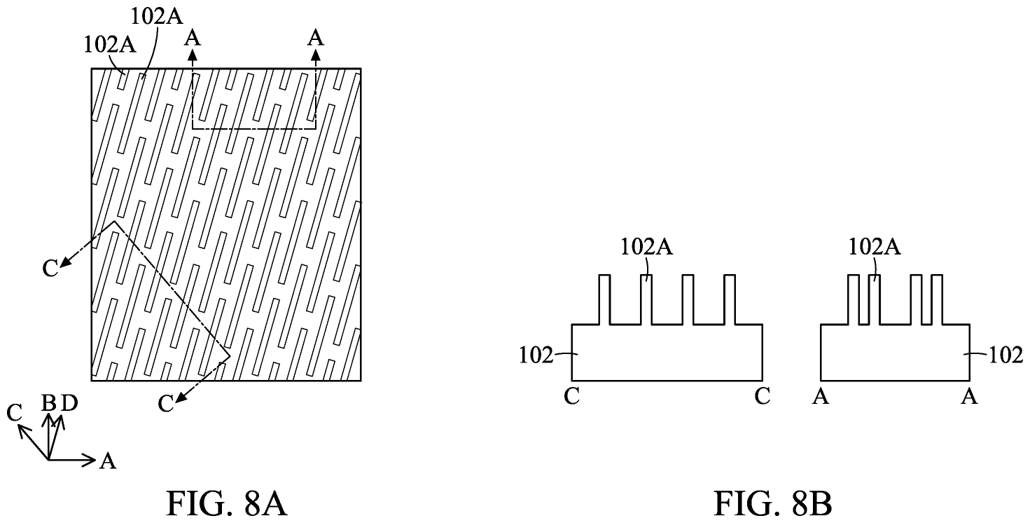

One or more etching processes are performed on the semiconductor structure of FIGS. 7A and 7B using the island patterns 110A to remove the third hard mask layer 108, the second hard mask layer 106, the first hard mask layer 104, and a portion of the semiconductor substrate 102 directly under the trenches T1 and the openings O4, as shown in FIGS. 8A and 8B. The third hard mask layer 108, the second hard mask layer 106, and the first hard mask layer 104 may be removed during the etching process or by additional processes. The etching process transfers the island patterns 110A into the semiconductor substrate 102, thereby forming active regions 102A.

Additional components can be formed over the semiconductor structure of FIGS. 8A and 8B to produce a semiconductor memory device. For example, embedded word lines extending through the active region 102A, bit lines over the active regions 102A, capacitor structures over the bit lines, and/or other applicable components can be formed. In some embodiments, the semiconductor memory device is a dynamic random-access memory (DRAM).

As described above, the embodiments of the present disclosure are direct to a self-aligned double patterning (SADP) technology. In accordance with some embodiments, the pillar patterns with diamond-like or diamond-shaped profiles, which are formed using lithography and etching processes, serve as the core patterns. Subsequently, the spacer layer is formed around the pillar patterns to define the gap patterns, which also have diamond-like or diamond-shaped profiles. Due to the approximate profiles of the core patterns and the gap patterns, the detection capability of measuring devices for patterns may be improved. Therefore, the manufacturing cost of the semiconductor memory devices can be reduced, and the manufacturing yield of the semiconductor memory devices can be improved.

What is claimed is:

1. A method for forming a semiconductor structure, comprising:
forming strip patterns over a semiconductor substrate;
forming a hard mask layer over the strip patterns;
forming a patterned photoresist layer over the hard mask layer, wherein the patterned photoresist layer has a plurality of first openings;
etching the hard mask layer using the patterned photoresist layer, wherein remaining portions of the hard mask layer form a plurality of pillar patterns that are separated from one another;
depositing a dielectric layer along the plurality of pillar patterns;
etching the dielectric layer to form a plurality of second openings;
removing the plurality of pillar patterns to form a plurality of third openings in the dielectric layer; and
etching the strip patterns using the dielectric layer as a mask.

2. The method for forming the semiconductor structure as claimed in claim 1, wherein etching the hard mask layer comprises:
transferring the plurality of first openings into the hard mask layer; and
enlarging the plurality of first openings in the hard mask layer until neighboring two of the enlarged first openings merge with each other.

3. The method for forming the semiconductor structure as claimed in claim 1, wherein in a plan view, one of the pillar patterns has a first side and a second side, wherein the second side is connected to the first side, and the first side meets the second side at an angle in a range from about 30 degrees to about 150 degrees.

4. The method for forming the semiconductor structure as claimed in claim 1, wherein the plurality of pillar patterns are arranged in an array, a first row of the array includes a first pillar pattern and a second pillar pattern arranged subsequently, a second row of the array includes a third pillar pattern and a fourth pillar pattern arranged subsequently, a first column of the array includes the first pillar pattern and the third pillar pattern arranged subsequently, and a second column of the array includes the second pillar pattern and the fourth pillar pattern arranged subsequently.

5. The method for forming the semiconductor structure as claimed in claim 4, wherein deposition of the dielectric layer is performed until a first portion of the dielectric layer along a sidewall of the first pillar pattern merges with a second portion of the dielectric layer along a sidewall of the second pillar pattern.

6. The method for forming the semiconductor structure as claimed in claim 5, wherein:
the first portion of the dielectric layer along the sidewall of the first pillar pattern merges with a third portion of the dielectric layer along a sidewall of the third pillar pattern,
the second portion of the dielectric layer along the sidewall of the second pillar pattern merges with a fourth portion of the dielectric layer along a sidewall of the fourth pillar pattern, and
the third portion of the dielectric layer along the sidewall of the third pillar pattern merges with the fourth portion of the dielectric layer along the sidewall of the fourth pillar pattern.

7. The method for forming the semiconductor structure as claimed in claim 6, wherein a gap is formed between the first portion of the dielectric layer and the fourth portion of the dielectric layer, and etching the dielectric layer comprises enlarging the gap to form one of the second openings.

8. The method for forming the semiconductor structure as claimed in claim 1, wherein the strip patterns are etched so that the strip patterns are cut into island patterns, and the method further comprises performing an etching process on the semiconductor substrate using the island patterns to form active regions.

9. A method for forming a semiconductor structure, comprising
forming a plurality of strip patterns over a semiconductor substrate;
forming a first hard mask layer over the plurality of strip patterns;
patterning the first hard mask layer to form a plurality of pillar patterns corresponding to the plurality of strip patterns, wherein the plurality of pillar patterns have diamond-like profiles;
forming a spacer layer surrounding the plurality of pillar patterns, wherein the spacer layer has a plurality of first openings staggered from the plurality of pillar patterns, and the plurality of first openings have diamond-like profiles;
removing the pillar patterns to form a plurality of second openings; and
etching the strip patterns using the spacer layer as a mask.

10. The method for forming the semiconductor structure as claimed in claim 9, wherein the plurality of first openings are aligned above the plurality of strip patterns, and the plurality of second openings are aligned above the plurality of strip patterns, the strip patterns have a first pitch in a first direction, the pillar patterns have a second pitch in the first direction, and the second pitch is greater than the first pitch.

11. The method for forming the semiconductor structure as claimed in claim 9, wherein patterning the first hard mask layer comprises:
etching the first hard mask layer using a patterned photoresist layer, wherein the patterned photoresist layer has a plurality of third openings, and the plurality of third openings have elliptical profiles.

12. The method for forming the semiconductor structure as claimed in claim 11, wherein patterning the first hard mask layer further comprises:
extending the plurality of third openings into the first hard mask layer and expanding laterally the plurality of third openings.

13. The method for forming the semiconductor structure as claimed in claim 9, wherein the diamond-like profiles of the pillar patterns have concave sides.

14. The method for forming the semiconductor structure as claimed in claim 9, wherein the plurality of first openings are arranged in a first array, and the plurality of second openings are arranged in a second array, wherein multiple rows of the first array are alternately arranged with multiple rows of the second array.

15. A semiconductor structure, comprising:
a substrate; and
a spacer layer over the substrate, wherein the spacer layer has a plurality of openings arranged in an array, and the plurality of openings comprises:
first openings arranged in a first row of the array; and
second openings arranged in a second row of the array, wherein the first openings are staggered from the second openings, and both the first openings and the second openings have diamond-like profiles.

16. The semiconductor structure as claimed in claim 15, further comprising:
strip patterns over the substrate and below the spacer layer, wherein the plurality of openings further comprises:
third openings arranged in a third row of the array, wherein the first openings are aligned with the third openings, and in a column direction of the array, a pitch between the third openings and the first openings is equal to a pitch between the strip patterns.

17. The semiconductor structure as claimed in claim 16, wherein in a row direction of the array, the pitch between the first openings is twice the pitch between the strip patterns.

18. The semiconductor structure as claimed in claim 15, wherein dimensions of the second openings are smaller than dimensions of the first openings.

19. The semiconductor structure as claimed in claim 15, wherein one of the first openings has a concave side.

20. The semiconductor structure as claimed in claim 15, wherein one of the first openings has two sides which intersect at an angle in a range from about 60 degrees to about 120 degrees.
